(19) United States
(12) Patent Application Publication
(10) Pub. No.: US 2006/0185711 A1
(43) Pub. Date: Aug. 24, 2006

(54) Storage container using a thermoelement

(75) Inventors: Woo Jong Bang, Seoul (KR); Jung-Owan Lee, Seoul (KR)

Correspondence Address: BACON & THOMAS, PLLC, 625 SLATERS LANE, FOURTH FLOOR, ALEXANDRIA, VA, 22314, US

(73) Assignee: DAEWOO ELECTRONICS Corporation, Seoul (KR)

(21) Appl. No.: 11/357,076

(22) Filed: Feb. 21, 2006

(30) Foreign Application Priority Data
Feb. 22, 2005 (KR) 10-2005-0014689
Feb. 22, 2005 (KR) 10-2005-0014690
Feb. 22, 2005 (KR) 10-2005-0014692
Jul. 1, 2005 (KR) 10-2005-0059007

(51) Int. Cl. H01L 35/02

(52) U.S. Cl. 136/230

(57) ABSTRACT

A storage container includes an inner case defining a storage chamber, an outer case disposed outside the inner case, and a thermoelement assembly. The thermoelement assembly includes a cold sink and a first heat transfer block respectively provided at an inner side and an outer side of the inner case, a heat sink and a second heat transfer block respectively provided at an outer side and an inner side of the outer case; and a thermoelement disposed inside the second heat transfer block. The second heat transfer block is detachably coupled with the first heat transfer block. The first heat transfer block has at one end a flange portion attached to the cold sink with the inner case interposed therebetween, and the second heat transfer block has at one end a flange portion attached to the heat sink with the outer case interposed therebetween.

### FIELD OF THE INVENTION

The present invention relates to a storage container using a thermoelement for cold-storage and hot-storage purpose and, more particularly, to a storage container including a thermoelement assembly capable of being detachably installed, thereby making maintenance and repair thereof easier.

### BACKGROUND OF THE INVENTION

As generally known in the art, a thermoelement is an element for use in a solid cooling system adapted to control a temperature by using a Peltier effect-dependent heat absorption and emission phenomenon that occurs at the opposite ends of the thermoelement when a direct current is applied to flow through a module comprised of different types of conductors (e.g., N-type and P-type semiconductors).

Unlike a coolant-circulated cooling system, the thermoelement cooling system requires no use of mechanical operating parts and hence causes no environmental problem. In this thermoelement cooling system, by applying a direct current to N-type and P-type semiconductors of a thermoelement, heat absorption occurs at one contact point where electrons absorb ambient heat energy and then move toward the inner part of the thermoelement, and heat emission takes place at the other contact point where the electrons emit the heat energy to the outside. This is referred to as a Peltier effect.

The thermoelement, which takes advantage of the Peltier effect, is capable of controlling the amount of heat absorption and emission depending on the intensity and direction of an electric current and requires no use of mechanical operating parts, thus providing an advantage in that the mounting position and orientation of the thermoelement has no effect on the operation thereof. For this reason, the thermoelement is widely used in producing a cooling device or a heating device.

Examples of storage containers using the thermoelement include a Kimchi (a kind of Korean foods) refrigerator, a compact refrigerator, a cold and hot storage container for an automotive vehicle, a constant temperature and humidity chamber, a dehumidifier, a grain storage container, a cosmetics storage container and a constant temperature chamber for medical use.

A various types of coolers and radiators are employed in these storage containers for the purpose of absorbing or radiating to the outside the heat generated from the thermoelement. Typically, a heat sink and a cold sink are used for this purpose. Shown in FIG. 1 by way of example is a conventional refrigerator that includes a heat emission arrangement with the heat sink and the cold sink.

A cabinet 1 for the refrigerator includes an inner case 10 for defining a storage chamber 2, an outer case 20 arranged to surround the inner case 10, and an insulating wall 30 provided between the inner case 10 and the outer case 20 for thermal insulation between the storage chamber 2 and the outside.

A heat transferring member 40 is provided in a heat transferring space of the insulating wall 30 within which a thermoelement 50 is disposed. A cold sink 60 that absorbs ambient heat is provided at one side, i.e., the storage chamber-side of the heat transferring member 40 and a heat sink 70 that emits the heat to the atmosphere is provided at the outer case-side of the heat transferring member 40.

An aluminum plate 52 of small thickness is disposed between the thermoelement 50 and the heat sink 70 in order to attach the heat sink 70 to the thermoelement 50. The aluminum plate 52 is attached at their opposite surfaces to the thermoelement 50 and the heat sink 70, respectively, via a thermally conductive grease layer 54.

There are also provided other thermally conductive grease layers 54 between the thermoelement 50 and the heat transferring member 40 and between the heat transferring member 40 and the cold sink 60.

The cold sink 60 is coupled to the heat transferring member 40 by using screws and the heat sink 70 is coupled to the insulating wall 30 by using screws. Provided at the front side of the cold sink 60 is a cooling fan (not shown) which helps the cold sink 60 to absorb heat.

In this type of refrigerator, heat is absorbed by the cold sink 60 attached to the front surface of the thermoelement 50 which serves to absorb and emit the heat while an electric current is applied.

Namely, the inside of the storage chamber 2 is cooled down as the surface of the cold sink 60 attached to the cold surface of the thermoelement 50 becomes cold, at which time heat loss is prevented by the insulating wall 30.

The heat sink 70 absorbs and then radiates to the outside the heat emitted from the other surface of the thermoelement 50.

According to the prior art refrigerator as described above, a heat treatment process is required several times to form the heat conductive grease layers 54 between the thermoelement 50 and the heat transferring member 40, between the heat transferring member 40 and the cold sink 60, and between the thermoelement 50 and the heat sink 70. This makes the assembling work time-consuming. Further, the manually performed assembling process is problematic in that it requires a great deal of time.

Another problem is the inability to gain access to and repair the thermoelement 50 which is kept hidden after foaming of the insulating wall 30.

### SUMMARY OF THE INVENTION

It is, therefore, an object of the present invention to provide a thermoelement assembly that, thank to the provision of a heat transfer block enclosing and sealing a thermoelement, helps improve the fittability and durability of the thermoelement and makes it possible to repair the thermoelement even after an insulating wall has been formed by foaming.

In accordance with an aspect of the present invention, there is provided a storage container including: an inner case defining a storage chamber, an outer case disposed outside the inner case, and a thermoelement assembly including: a cold sink and a first heat transfer block respectively provided at an inner side and an outer side of the inner case; a heat sink and a second heat transfer block respectively provided at an outer side and an inner side of the outer case; and a thermoelement disposed inside the second heat transfer block, wherein the second heat transfer block is detachably coupled with the first heat transfer block, and an insulating material made of an urethane resin is filled between the inner case and the outer case.

Preferably, the first heat transfer block has at one end a flange portion attached to the cold sink by using a fastening unit with the inner case interposed between the flange portion and the cold sink, and the second heat transfer block has at one end a flange portion attached to the heat sink by using a fastening unit with the outer case interposed between the flange portion of the second heat transfer block and the heat sink.

Further, it is preferable that the first heat transfer block has at an outer periphery of the other end a coupling portion having coupling holes, and the second heat transfer block has at the other end engaging portions inserted into the respective coupling holes.

In accordance with another aspect of the present invention, there is provided a storage container including: an inner case defining a storage chamber, an outer case disposed outside the inner case, and a thermoelement assembly including: a cold sink adapted to absorb ambient heat and having a cover plate; a heat sink adapted to emit the heat and having a cover plate; a thermoelement receiving part disposed on one surface of the cover plate of the heat sink, the thermoelement receiving part comprised of a base portion disposed the one surface of the cover plate of the heat sink and a block protruding from the base portion and having an open cavity; and a thermoelement disposed within the open cavity of the block of the thermoelement receiving part, wherein the cold sink has a contact portion protruding from one surface of the cover plate of the cold sink, and when coupled, the contact portion contacts with the thermoelement in the block of thermoelement receiving part, so that the cold sink, the thermoelement and the heat sink are thermally connected with one another.

The thermoelement assembly may further comprise a heat transfer plate disposed between the heat sink and the cold sink, the block having a guide rim at its free end, the heat transfer plate having an aperture at its center formed in alignment with the open cavity of the block, the heat transfer plate having a coupling portion protruding from a periphery of the aperture toward the block, the coupling portion having a coupling groove engaged with the guide rim of the block, the contact portion of the cold sink inserted into the open cavity of the block through the aperture of the heat transfer plate.

Preferably, the base portion of the thermoelement receiving part has a coupling boss and the heat transfer plate has a guide boss receiving the coupling boss, the thermoelement receiving part coupled with the heat transfer plate by a screw tightened through the coupling boss and the guide boss.

The thermoelement assembly may further comprise thermally conductive grease layers applied to front and rear surfaces of the thermoelement.

In accordance with still another aspect of the present invention, there is provided a storage container having an inner case, an outer case, a heat transferring space formed at a prescribed position between the inner case and the outer case, and a thermoelement assembly mounted through the heat transferring space, comprising: a first shield member having a flange portion secured to the inner case and a tubular portion enclosing one part of the thermoelement; a second shield member having a flange portion secured to the outer case and a tubular portion enclosing the other part of the thermoelement; a sealing member for sealing a contact point between the first shield member and the second shield member; and an insulating wall formed with a liquid urethane resin, the urethane resin being filled between the inner case and the outer case.

In accordance with still another aspect of the present invention, there is provided a storage container comprising an inner case defining a storage chamber, an outer case disposed outside the inner case and a thermoelement assembly, the thermoelement assembly including a primary cold sink disposed at an inner side of the inner case and having a multiplicity of cooling fins, a heat sink disposed at an outer side of the outer case and a thermoelement disposed between the cold sink and the heat sink, wherein the thermoelement assembly further includes an auxiliary cold sink having a multiplicity of cooling fins alternately disposed between the cooling fins of the primary cold sink.

### BRIEF DESCRIPTION OF THE DRAWINGS

The above and other objects and features of the present invention will become apparent from the following description of preferred embodiments, given in conjunction with the accompanying drawings, in which:

FIG. 1 a partial cross-sectional view showing a prior art storage container using a thermoelement;

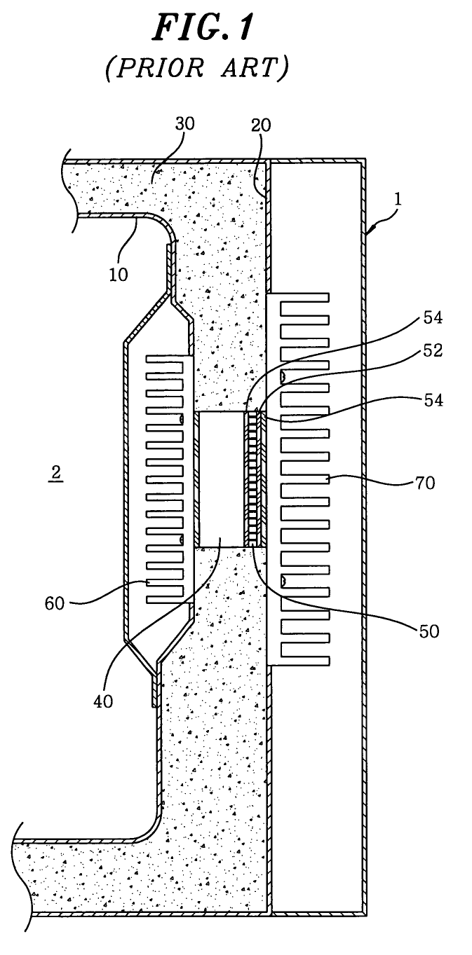

FIG. 2 is a partial cross-sectional view illustrating a storage container using a thermoelement assembly in accordance with a first embodiment of the present invention;

FIG. 3 is an exploded perspective view of the thermoelement assembly shown in FIG. 2;

FIG. 4 an exploded perspective view showing a thermoelement assembly in accordance with a second embodiment of the present invention;

FIG. 5 is a perspective view of the thermoelement assembly in FIG. 4;

FIG. 6 is a partial cross-sectional view showing a storage container using the thermoelement assembly shown in FIG. 4;

FIG. 7 a partial cross-sectional view illustrating a storage container using a thermoelement assembly in accordance with a third embodiment of the present invention;

FIG. 8 a partial cross-sectional view showing a storage container using a thermoelement assembly in accordance with a fourth embodiment of the present invention; and

FIG. 9 is a perspective view of a cold sink employed in the thermoelement assembly depicted in FIG. 8.

### DETAILED DESCRIPTION OF THE PREFERRED EMBODIMENTS

Hereinbelow, preferred embodiments of the present invention will be described in detail with reference to the accompanying drawings.

### First Embodiment

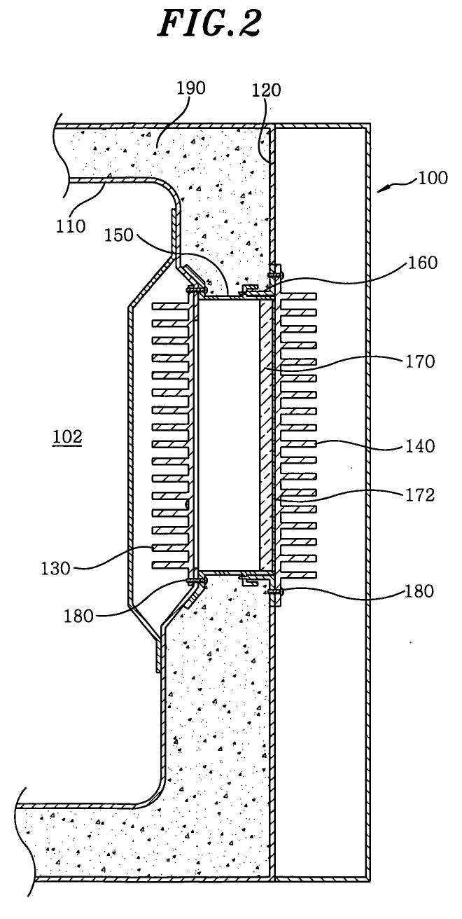

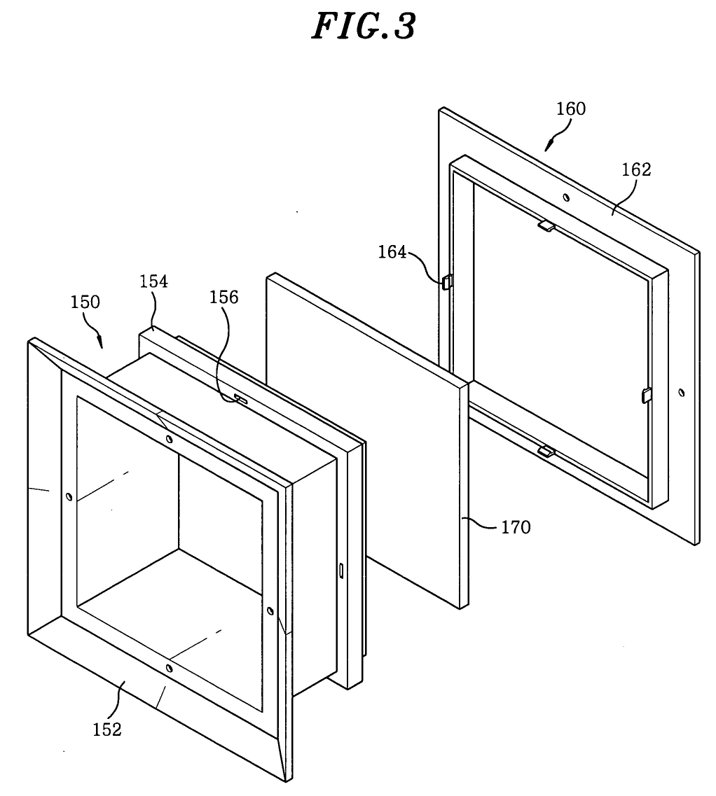

FIG. 2 is a partial cross-sectional view showing a storage container using a thermoelement assembly in accordance with a first embodiment of the present invention, and FIG. 3 is an exploded perspective view of the thermoelement assembly depicted in FIG. 2.

Referring to FIG. 2, a storage container includes a cabinet 100, an inner case 110 for defining a storage chamber 102 inside the cabinet 100, and an outer case 120 arranged to surround the inner case 110.

A cold sink 130 serving to absorb ambient heat for the cooling purpose is provided at the inner surface side, i.e., the storage chamber-side of the inner case 110 and a heat sink 140 serving to emit the heat to the atmosphere is provided at the outer side of the outer case 120.

In the first embodiment of the present invention, a first heat transfer block 150 is provided at the outer side of the inner case 110 and a second heat transfer block 160 is provided at the inner side of the outer case 120.

Referring to FIG. 3, the first heat transfer block 150 is of a rectangular shape with an internal space but may be of a polygonal or cylindrical shape. The first heat transfer block 150 has at one end a flange portion 152 which is closely attached to the inner case 110 and, at an outer periphery of the other end, a coupling portion 154 with a plurality of coupling holes 156.

Likewise, the second heat transfer block 160 is of a rectangular shape with an internal space for partial reception of the first heat transfer block 150 but may be of a polygonal or cylindrical shape. The second heat transfer block 160 has at one end a flange portion 162 which is closely attached to the outer case 120 and, at the other end, hook-shaped engaging portions 164 which are inserted into and engaged with the respective coupling holes 156 of the first heat transfer block 150. A thermoelement 170 is provided in the internal space of the second heat transfer block 160 to be fixed therein via a thermally conductive grease layer 172.

Accordingly, the coupling of the first heat transfer block 150 with the second heat transfer block 160 is rendered by inserting the hook-shaped engaging portions 164 into the coupling holes 156. The flange portion 152 of the first heat transfer block 150 is secured to the cold sink 130 with the inner case 110 therebetween by using fastening means. Similarly, the flange portion 162 of the second heat transfer block 160 is secured to the heat sink 140 with the outer case 120 therebetween fastening means. In this embodiment, screws 180 are used as the fastening means, but other suitable fastening elements may be used.

After the first heat transfer block 150 and the second heat transfer block 160 coupled together is installed in a heat transfer space of the storage container, an insulating wall 190 is created around the first heat transfer block 150 and the second heat transfer block 160 by foaming a foamable material, e.g., urethane, between the inner case 110 and the outer case 120.

There will now be described an assembling process of the thermoelement assembly for a storage container in accordance with the first preferred embodiment of the present invention.

Referring back to FIG. 2, the flange portion 152 of the first heat transfer block 150 is first placed against the outer surface of the inner case 110, and then the first heat transfer block 150 is secured to the cold sink 130 disposed at the inner surface of the inner case 110 with the inner case therebetween.

Subsequently, the second heat transfer block 160 carrying the thermoelement 170 bonded thereto via the heat conductive grease layer 172 is coupled to the first heat transfer block 150. The coupling is rendered by inserting the hook-shaped engaging portions 164 of the second heat transfer block 160 into the coupling holes 156 of the first heat transfer block 150.

Then, the heat sink 140 is secured to the flange portion 162 of the second heat transfer block 160 by means of the screws 180.

Under the state that the first heat transfer block 150 and the second heat transfer block 160 are coupled together, urethane foam is filled into the space between the inner case 110 and the outer case 120 to thereby form the insulating wall 190.

According to the thermoelement assembly for a storage container described above, the thermoelement 170 can be simply and easily installed by coupling together the first heat transfer block 150 and the second heat transfer block 160 to which the thermoelement 170 is attached in advance. Furthermore, the thermoelement 170 has enhanced durability because it remains sealed within the heat transfer blocks 150 and 160.

Moreover, during the process of forming the insulating wall 190, the urethane foam is prevented from infiltrating into inside due to the first and second heat transfer blocks 150 and 160. Even after the insulating wall 190 has been formed by the urethane foaming, it is possible to repair the thermoelement 170 if damaged, by separating the heat sink 140, disengaging the engaging portions 164 of the second heat transfer block 160 from the coupling holes 156 and then removing the thermoelement 170.

### Second Embodiment

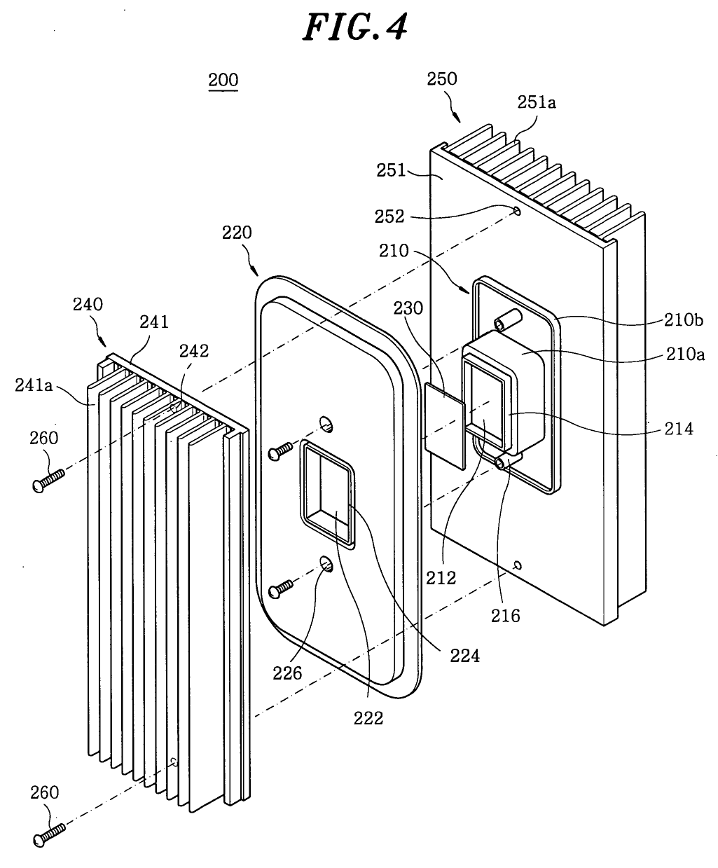

A second embodiment of the present invention will now be described in detail with reference to FIGS. 4 through 6.

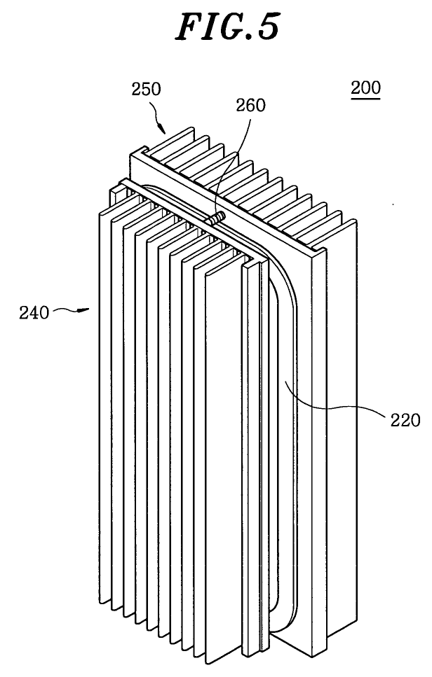

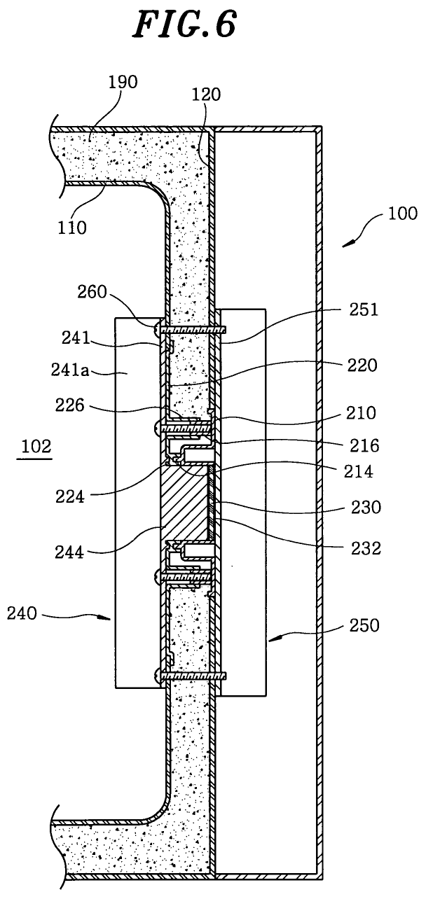

FIG. 4 is an exploded perspective view showing a thermoelement assembly according to a second embodiment of the present invention, FIG. 5 is a perspective view of the thermoelement assembly depicted in FIG. 4, and FIG. 6 is a partial cross-sectional view showing a storage container provided with the thermoelement assembly shown in FIG. 4.

A thermoelement assembly 200 in accordance with the second embodiment of the present invention includes a cold sink 240 serving to absorb ambient heat, a heat sink 250 serving to radiate the heat to the outside, and a thermoelement 230 disposed between the cold sink 240 and the heat sink 250.

As illustrated in FIG. 4, the cold sink 240 is comprised of a cover plate 241 and a multiplicity of cooling fins 241a provided on one surface, i.e., the front surface, of the cover plate 241. Further, the heat sink 250 is comprised of a cover plate 251 and a multiplicity of cooling fins 251a provided on one surface, i.e., the rear surface, of the cover plate 251.

In the thermoelement assembly 200 in accordance with the second embodiment of the present invention, a thermoelement receiving part 210 is disposed on the other surface, i.e., the front surface, of the cover plate 251 of the heat sink 250. The thermoelement receiving part 210 is comprised of a base portion 210b provided on the front surface of the cover plate 251 of the heat sink 250 and a block 210a of, e.g., a rectangular shape protruding from the base portion 210b. The thermoelement 230 is disposed within an open cavity 212 of the block 210a. It is preferred that thermally conductive grease layers 232 be applied on the opposite surfaces, i.e., the front and rear surfaces, of the thermoelement 230. The thermoelement receiving part 210 may be produced by, e.g., injection-molding a synthetic resin. A guide rim 214 is formed along the free end of the block 210a.

In addition, a heat transfer plate 220 is disposed between the heat sink 250 and the cold sink 240 and has at its center an aperture 222 formed in alignment with the open cavity 212 of the block 210a. Protruding from the periphery of the aperture 222 toward the block 210a is a coupling portion 224 that has a coupling groove engaging with the guide rim 214 formed on the free end of the block 210a. A couple of coupling bosses 216 protrude from the base portion 210b of the thermoelement receiving part 210, and a couple of guide bosses 226 are formed on the heat transfer plate 220 correspondingly to the coupling bosses 216. The heat transfer plate 220 can be fixedly secured to the thermoelement receiving part 210 by placing the heat transfer plate 220 such that the coupling groove of the coupling portion 224 of the heat transfer plate 220 is brought into engagement with the guide rim 214 of the block 210a and the coupling bosses 216 are inserted into the guide bosses 226, and then fitting screws into the coupling bosses 216 through the guide bosses 226.

A contact portion 244 having substantially the same size as that of the thermoelement 230 protrudes from the rear surface of the cover plate 241 of the cold sink 240 as best shown in FIG. 6. When coupled, the contact portion 244 extends through the aperture 222 of the heat transfer plate 220 and makes contact with the thermoelement 230 within the block 210a via the thermally conductive grease layer 232. The height of the contact portion 244 is properly selected such that the thermoelement 230 can be pressed against the front surface of the cover plate 251 of the heat sink 250 through the thermally conductive grease layer 232.

Formed through each of the cover plates 241 and 251 of the cold sink 240 and the heat sink 250 are screw holes 242 and 252 into which screws 260 are fastened to couple the cold sink 240 and the heat sink 250 together.

Although the cold sink 240 and the heat sink 250 are coupled by the screws 260, riveting or other suitable coupling methods may be employed for that purpose.

Referring to FIG. 6, there is shown a storage container provided with the thermoelement assembly 200 in accordance with the second embodiment of the present invention set forth above. The process of fitting the thermoelement assembly 200 to a storage container is as follows.

Initially, the guide bosses 226 of the heat transfer plate 220 is coupled with the coupling bosses 216 of the base portion 210b of the thermoelement receiving part 210 and, concurrently, the guide rim 214 of the block 210a is inserted into the coupling groove of the coupling portion 224, thus bringing the heat transfer plate 220 into alignment with the thermoelement receiving part 210. Then, the screws are inserted through the guide bosses 226 and fastened to the coupling bosses 216 to thereby fixedly secure the heat transfer plate 220 to the thermoelement receiving part 210.

Subsequently, the cover plate 251 of the heat sink 250 is pressed against the outer surface of the outer case 120 of the storage container 100, after which the rear surface of the base portion 210b of the thermoelement receiving part 210 is brought into close contact with the front surface of the cover plate 251 of the heat sink 250 through a thermoelement assembly installation space of the storage container 100. Under this state, the thermoelement 230 having the thermally conductive grease layers 232 on its opposite surfaces is placed within the open cavity 212 of the block 210a. Then, from inside the inner case 110 of the storage container 100, the contact portion 244 of the cold sink 240 is inserted into the open cavity 212 via the aperture 222. This ensures that the thermoelement 230 is pushed inwards within the open cavity 212 to eventually make close contact with the heat sink 250.

Under the above-noted state, the screws 260 are tightened through the coupling holes 242 and 252 of the cover plates 241 and 251 and the coupling holes (not shown) of the inner case 110 and the outer case 120, thus fixedly securing the thermoelement assembly 200 to the storage container 100.

It should be appreciated that the installing order of the components of the thermoelement assembly 200 is subject to no particular limitation and may be changed, if needed.

According to the thermoelement assembly 200 of the present embodiment, the installing and uninstalling works can be conducted in a simpler manner. Moreover, it becomes possible to enhance the durability of the thermoelement 230, thank to the fact that the thermoelement 230 is disposed within a closed space of the block 210a.

In addition, according to the thermoelement assembly 200 of the present embodiment, Moreover, during the process of forming the insulating wall 190, the urethane foam is prevented from infiltrating into the thermoelement receiving part 210. Even after the insulating wall 190 has been formed by the urethane foaming, the thermoelement 170 can be repaired with ease by separating the heat sink 250 and then detaching the heat transfer block 210 from the heat transfer plate 220.

### Third Embodiment

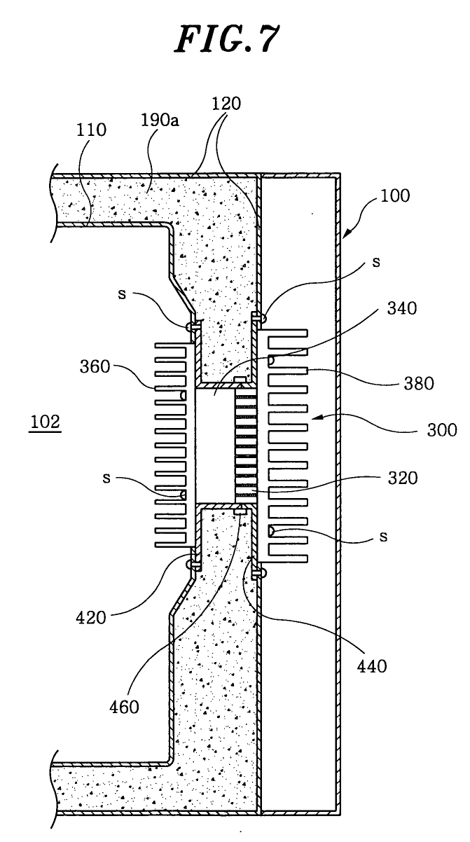

A third embodiment of the present invention will now be described in detail with reference to FIG. 7.

FIG. 7 is a cross-sectional view showing a storage container using a thermoelement assembly in accordance with a third embodiment of the present invention.

In the third embodiment of the present invention, a thermoelement assembly 300 is installed in a heat transferring space 340 as similarly to the conventional storage container. Further, an urethane resin of liquid phase is filled in the space between the inner case 110 and the outer case 120 to form an insulating wall 190a. To this end, a shield unit is additionally provided to keep the liquid urethane resin from infiltrating toward the thermoelement assembly 300 in the filling process, thereby reducing the performance deterioration thereof.

The shield unit includes a first shield member 420 surrounding the front part of a thermoelement 320 in the thermoelement assembly 300 and a second shield member 440 surrounding the rear part of the thermoelement 320 in the thermoelement assembly 300.

The first shield member 420 is formed in a tubular shape such that it can make contact with and shield the outer periphery of the thermoelement 320. The first shield member 420 has at its frontal edge a flange portion which is attached to the rear surface of the inner case 110 by using screws S.

Similarly, the second shield member 440 is formed in a tubular shape corresponding to the outer periphery of the thermoelement 320 and has at its rear edge a flange portion which is attached to the front surface of the outer case 120 by using screws S.

Accordingly, the thermoelement assembly 300 is completely shielded by the shield members 420 and 440 in such a condition that the liquid urethane resin can be filled outside the shield members 420 and 440 to form the insulating wall 190a. In the meantime, a separate sealing member 460 is provided around the contact point where the rear edge of the first shield member 420 meets with the front edge of the second shield member 440. This is to avoid any leakage of the liquid urethane resin which would otherwise occur through a gap of the contact point.

The reason for forming the insulating wall 190a with an urethane resin is that the urethane resin is superior in insulation performance to EPA used in the prior art. In view of the fact that the liquid urethane resin is filled at a temperature of about 70° C., the shield members 420 and 440 and the sealing member 460, which shield the liquid urethane resin, may be made of such a synthetic resin as polypropylene or the like that are less susceptible to thermal deformation at that temperature.

In a conventional method, a preformed solid EPA is inserted into a space between the inner case 110 and the outer case 120 that has a greater tolerance for facilitated insertion thereof. This results in the thermoelement assembly 300 being partially exposed to the gap existing between the solid EPA and the inner and outer cases 110 and 120, thus causing heat loss to the thermoelement assembly 300. In contrast, in this embodiment of the present embodiment, by using the shield members 420 and 440, it becomes possible to fill the liquid urethane resin and completely shield the thermoelement assembly 300, thereby avoiding any heat loss that has been encountered in the prior art methods. Furthermore, use of the urethane resin having a superior insulation performance helps to prevent heat loss, which enhances the cooling performance of the thermoelement assembly 300 at the side of the storage chamber 102.

A preferred order of installing the thermoelement assembly 300 to a storage container is as follows. The first step is to secure the first shield member 420 and the second shield member 440 to the inner case 110 and the outer case 120, after which the sealing member 460 is attached around the contact point of the first shield member 420 and the second shield member 440. Then, the thermoelement assembly 300 is fixedly secured with respect to the inner case 110 and the outer case 120 in such a manner that the thermoelement 320 lies within a space shielded by the first shield member 420 and the second shield member 440. Thereafter, a liquid urethane resin is filled into the space between the inner case 110 and the outer case 120 and then cured to form the insulating wall 190a.

The thermoelement assembly 300 used in the present embodiment may be the ones of the first and second embodiments set forth earlier or a conventional thermoelement assembly.

### Fourth Embodiment

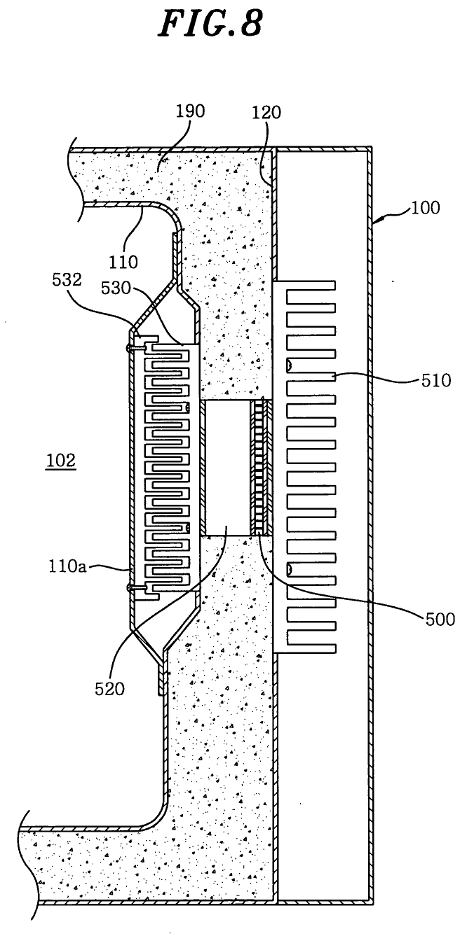

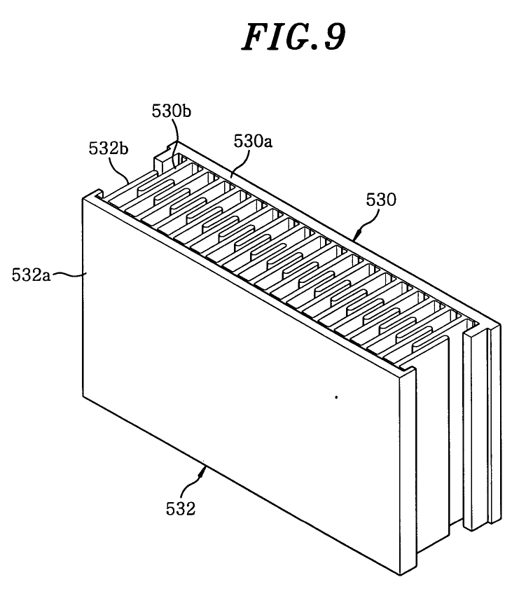

A fourth embodiment of the present invention will now be described in detail with reference to FIGS. 8 and 9.

FIG. 8 a cross-sectional view showing a storage container that has a thermoelement assembly according to a fourth embodiment of the present invention, and FIG. 9 is a perspective view of a cold sink employed in the thermoelement assembly depicted in FIG. 8.

As illustrated in FIGS. 8 and 9, a thermoelement-type storage container includes a thermoelement 500, a heat sink 510 disposed in contact with the heat-emitting side of the thermoelement 500, a heat transferring space 520 provided at the heat-absorbing side of the thermoelement 500, and a primary cold sink 530 arranged in a confronting relationship with the heat-absorbing side of the thermoelement 500.

According to the present embodiment, an auxiliary cold sink 532 is attached to an inner case 110 to face the primary cold sink 530 which serves to absorb ambient heat for the cooling purpose.

The primary cold sink 530 and the auxiliary cold sink 532 are preferably made of aluminum with a high thermal conductivity. The primary cold sink 530 and the auxiliary cold sink 532 are respectively provided with cover plates 530a and 532a and a multiplicity of cooling fins 530b and 532b that protrude toward each other from the cover plates 530a and 532a in a mutually interleaving relationship.

Accordingly, the auxiliary cold sink 532, which is arranged to face the primary cold sink 530, provides a double cooling fin array wherein the cooling fins 530b of the primary cold sink 530 are alternately disposed between the cooling fins 532b of the auxiliary cold sink 532.

The storage container incorporating the above-noted thermoelement according to a fourth embodiment of the present invention is fabricated and operated as follows.

Initially, the primary cold sink 530 having the cover plate 530a and the cooling fins 530b is secured to the side of the heat transferring space 520 by means of a fastener means, e.g., screws, and the auxiliary cold sink 532 is attached to a bracket 110a, which forms a part of the inner case 110, in such a manner that the cooling fins 530b of the primary cold sink 530 are alternately disposed between the cooling fins 532b of the auxiliary cold sink 532. This creates a single cold sink unit comprised of the primary cold sink 530 and the auxiliary cold sink 532.

Under this state, if an electric current is applied to the thermoelement 500, the heat-absorbing side of the thermoelement 500 meeting with the heat transferring space 520 is cooled down to thereby cool the air present in the heat transferring space 520, the primary cold sink 530 and the auxiliary cold sink 532 in the named sequence. This enlarges the heat conducting area and enhances the cooling efficiency.

Concurrently, the heat-emitting side of the thermoelement 500 coupled with the heat sink 510 transfers heat to the heat sink 510 which in turn radiates the heat to the outside.

The primary cold sink 530 and the auxiliary cold sink 532, which form a double cooling fin array comprised of the cooling fins 530b and 532b, are capable of exhibiting the cooling efficiency and improving the refrigerating performance of a storage container. Such is the case in an atmosphere of elevated temperature as in summer.

As described in the foregoing, the thermoelement assembly for storage container according to the present invention helps improve the fittability and durability of the thermoelement and makes it possible to repair the thermoelement even after an insulating wall has been formed by foaming. This is due to the provision of a heat transfer block enclosing and sealing the thermoelement.

While the invention has been shown and described with respect to the preferred embodiments, it will be understood by those skilled in the art that various changes and modification may be made without departing from the spirit and scope of the invention as defined in the appended claims.

What is claimed is:

1. A storage container comprising:
an inner case defining a storage chamber;
an outer case disposed outside the inner case; and
a thermoelement assembly including:
a cold sink and a first heat transfer block respectively provided at an inner side and an outer side of the inner case;
a heat sink and a second heat transfer block respectively provided at an outer side and an inner side of the outer case; and
a thermoelement disposed inside the second heat transfer block,
wherein the second heat transfer block is detachably coupled with the first heat transfer block.

2. The storage container of claim 1, wherein the first heat transfer block has at one end a flange portion attached to the cold sink by using a fastening unit with the inner case interposed between the flange portion and the cold sink, and the second heat transfer block has at one end a flange portion attached to the heat sink by using a fastening unit with the outer case interposed between the flange portion of the second heat transfer block and the heat sink.

3. The storage container of claim 2, wherein the first heat transfer block has at an outer periphery of the other end a coupling portion having coupling holes, and the second heat transfer block has at the other end engaging portions inserted into the respective coupling holes.

4. A storage container comprising:
an inner case defining a storage chamber;
an outer case disposed outside the inner case; and
a thermoelement assembly including:
a cold sink attached to the inner case, the cold sink serving to absorb ambient heat and having a cover plate;
a heat sink attached to the outer case, the heat sink serving to emit the heat and having a cover plate;
a thermoelement receiving part disposed on one surface of the cover plate of the heat sink, the thermoelement receiving part comprised of a base portion disposed the one surface of the cover plate of the heat sink and a block protruding from the base portion and having an open cavity; and
a thermoelement disposed within the open cavity of the block of the thermoelement receiving part,
wherein the cold sink has a contact portion protruding from one surface of the cover plate of the cold sink, and when coupled, the contact portion contacts with the thermoelement in the block of thermoelement receiving part, so that the cold sink, the thermoelement and the heat sink are thermally connected with one another.

5. The storage container of claim 4, wherein the thermocouple assembly further includes a heat transfer plate disposed between the heat sink and the cold sink, the block having a guide rim at its free end, the heat transfer plate having an aperture at its center formed in alignment with the open cavity of the block, the heat transfer plate having a coupling portion protruding from a periphery of the aperture toward the block, the coupling portion having a coupling groove engaged with the guide rim of the block, the contact portion of the cold sink inserted into the open cavity of the block through the aperture of the heat transfer plate.

6. The storage container of claim 5, wherein the base portion of the thermoelement receiving part has a coupling boss and the heat transfer plate has a guide boss receiving the coupling boss, the thermoelement receiving part coupled with the heat transfer plate by a screw tightened through the coupling boss and the guide boss.

7. The storage container of claim 4, wherein the thermocouple assembly further includes thermally conductive grease layers applied to front and rear surfaces of the thermoelement.

8. A storage container having an inner case, an outer case, a heat transferring space formed at a prescribed position between the inner case and the outer case, and a thermoelement assembly mounted through the heat transferring space, comprising:
a first shield member having a flange portion secured to the inner case and a tubular portion enclosing one part of the thermoelement;
a second shield member having a flange portion secured to the outer case and a tubular portion enclosing the other part of the thermoelement;
a sealing member for sealing a contact point between the first shield member and the second shield member; and
an insulating wall formed with a liquid urethane resin, the urethane resin being filled between the inner case and the outer case.

9. A storage container comprising an inner case defining a storage chamber, an outer case disposed outside the inner case and a thermoelement assembly, the thermoelement assembly including a primary cold sink disposed at an inner side of the inner case and having a multiplicity of cooling fins, a heat sink disposed at an outer side of the outer case and a thermoelement disposed between the cold sink and the heat sink,
wherein the thermoelement assembly further includes an auxiliary cold sink having a multiplicity of cooling fins alternately disposed between the cooling fins of the primary cold sink.
